(19) United States
(12) Patent Application Publication
(10) Pub. No.: US 2010/0242500 A1
(43) Pub. Date: Sep. 30, 2010

(54) THERMAL SWITCH FOR SUPERCONDUCTING MAGNET COOLING SYSTEM

(76) Inventors: Evangelos T. Laskaris, Schenectady, NY (US); Kathleen M. Amm, Clifton Park, NY (US); David Thomas Ryan, N. Yorks (GB); Xianrui Huang, Clifton Park, NY (US); J. Anne Ryan, N. Yorks (GB)

Correspondence Address: GENERAL ELECTRIC COMPANY;GLOBAL RESEARCH, ONE RESEARCH CIRCLE, BLDG. K1-3A59, NISKAYUNA, NY, 12309, US

(21) Appl. No.: 11/530,267

(22) Filed: Sep. 8, 2006

(51) Int. Cl. F25B 19/00; G01R 33/48

(52) U.S. Cl. 62/51.1; 324/318

(57) ABSTRACT

The present invention provides an apparatus and method for automatically disconnecting a cryocooler from a cold mass reservoir of a MR system. A cryocooler thermal link includes a first end plate configured to be thermally connected to a cryocooler and a second end plate configured to be thermally connected to a cold mass. A wall encloses a space between the first and the second end plates, the wall having a first end attached to the first end plate and a second end attached to the second end plate. A working fluid is positioned in the space.

### BACKGROUND OF THE INVENTION

The present invention relates generally to superconducting magnet systems and, more particularly, to automatic thermal connection and disconnection between a cryocooler and a cold mass reservoir of the superconducting magnet system.

Exemplary superconducting magnet systems operating in an AC environment include a transformer, a generator, a motor, superconducting magnet energy storage (SMES), and a magnetic resonance (MR) system. Although a conventional MR magnet operates in a DC mode, some MR magnets may operate under an AC magnetic field from the gradient coils when the gradient leakage field to the magnet is high. Such an AC magnetic field generates AC losses in the magnet. An illustrative discussion of exemplary details of the MR system is presented, for explanatory purposes.

When a substance such as human tissue is subjected to a uniform magnetic field (polarizing field B₀), the individual magnetic moments of the spins in the tissue attempt to align with this polarizing field, but process about it in random order at their characteristic Larmor frequency. If the substance, or tissue, is subjected to a magnetic field (excitation field B₁) which is in the x-y plane and which is near the Larmor frequency, the net aligned moment, or “longitudinal magnetization”, M_{z}, may be rotated, or “tipped”, into the x-y plane to produce a net transverse magnetic moment Mₜ. A signal is emitted by the excited spins after the excitation signal B₁ is terminated and this signal may be received and processed to form an image.

When utilizing these signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received NMR signals are digitized and processed to reconstruct the image using one of many well known reconstruction techniques.

MR systems typically use superconducting magnets, often with multiple coils to generate the uniform magnetic field. These superconducting magnets are part of a cold mass cooled by liquid helium. The magnets are made typically of niobium-titanium material that is cooled to a temperature of 4.2 K with liquid helium. Often, a cryocooler is used to re-condense helium that boils off due to the heat load on the cold mass. This has the disadvantage of requiring a supply of liquid helium, which is expensive and may not be available in remote areas and underdeveloped countries. Furthermore, in the event of a power or mechanical failure of the cooling system, only the latent heat of the helium reserve is available to continue operation before the loss of operation of the superconducting magnets occurs.

Frequently, the cold mass is cooled to superconducting temperatures directly by using a cryocooler. In order for the cryocooler to cool the cold mass of the device directly, the cryocooler and the cold mass must be in direct thermal contact. However, in the event of failure of the cryocooler, the cryocooler will quickly warm to room temperature. Due to the direct thermal short of the cryocooler to the cold mass, the cold mass will warm quickly as well, which leads to a loss of superconducting operation of the magnet and magnet quench.

Additionally, it is occasionally necessary to disconnect the cryocooler from the cooling system for service or replacement. Typically, this requires bringing the cooling system to room temperature. The disconnection process is time-consuming and requires the MR system to be shut down for long periods of time. This is especially a problem when the repairs are not scheduled, which may result in patients having to re-schedule procedures.

It would therefore be desirable to have a system and method capable of quickly and automatically disconnecting and automatically reconnecting the cryocooler from thermal contact with the cold mass of the device in the event of failure of the cryocooler. It would further be desirable to enable temporary disconnection of the cryocooler from the cold mass in order to service and/or replace the cryocooler, without having to warm the entire cold mass to room temperature.

### BRIEF DESCRIPTION OF THE INVENTION

The present invention provides a system and method of disconnecting a cryocooler from a cold mass reservoir of an MR system that overcomes the aforementioned drawbacks. A thermal link having a working fluid is disposed between the cryocooler and the cold mass reservoir. During operation of the cryocooler, heat transfer is dominated by boiling, or phase change of the working fluid, serving as a thermal short between the cryocooler and the cold mass reservoir. When operation of the cryocooler is suspended, heat transfer within the thermal link is dominated by conduction of the working fluid, serving as a thermal open between the cryocooler and the cold mass reservoir.

In accordance with one aspect of the invention, a cryocooler thermal link includes a first end plate configured to be thermally connected to a cryocooler and a second end plate configured to be thermally connected to a cold mass. A wall encloses a space between the first and the second end plates and has a first end attached to the first end plate and a second end attached to the second end plate. The cryocooler thermal link also includes a working fluid positioned in the space.

The present invention is also directed to an MRI system including a superconducting magnet assembly cold mass, a cryocooler, and a thermal switch positioned between the cold mass and the cryocooler. The thermal switch includes a first end plate in thermal contact with the cryocooler and a second end plate in thermal contact with the cold mass. A wall is connected to the first end plate and the second end plate forming an enclosure. A working fluid is contained in the enclosure and is in thermal contact with the first end plate and the second end plate.

The present invention is also direct to a method of controlling heat transfer between a cryocooler having a first end plate and a cold mass having a second end plate. The method includes the steps of forming an enclosure between the first end plate and the second end plate, orienting the first end plate gravitationally above the second end plate, and filling the enclosure with a working fluid. The working fluid is in thermal contact with the first end plate and the second end plate.

Various other features and advantages of the present invention will be made apparent from the following detailed description and the drawings.

### BRIEF DESCRIPTION OF THE DRAWINGS

The drawings illustrate one preferred embodiment presently contemplated for carrying out the invention.

In the drawings:

FIG. 1 is a schematic block diagram of an MR imaging system for use with the present invention.

FIG. 2 is a schematic block diagram of a portion of a cryocooling system in accordance with an embodiment of the present invention.

FIG. 3 shows the thermal link of FIG. 2 during operation of the cryocooling system.

FIG. 4 shows the thermal link of FIG. 2 after suspension of operation of the cryocooling system.

### DETAILED DESCRIPTION OF THE PREFERRED EMBODIMENT

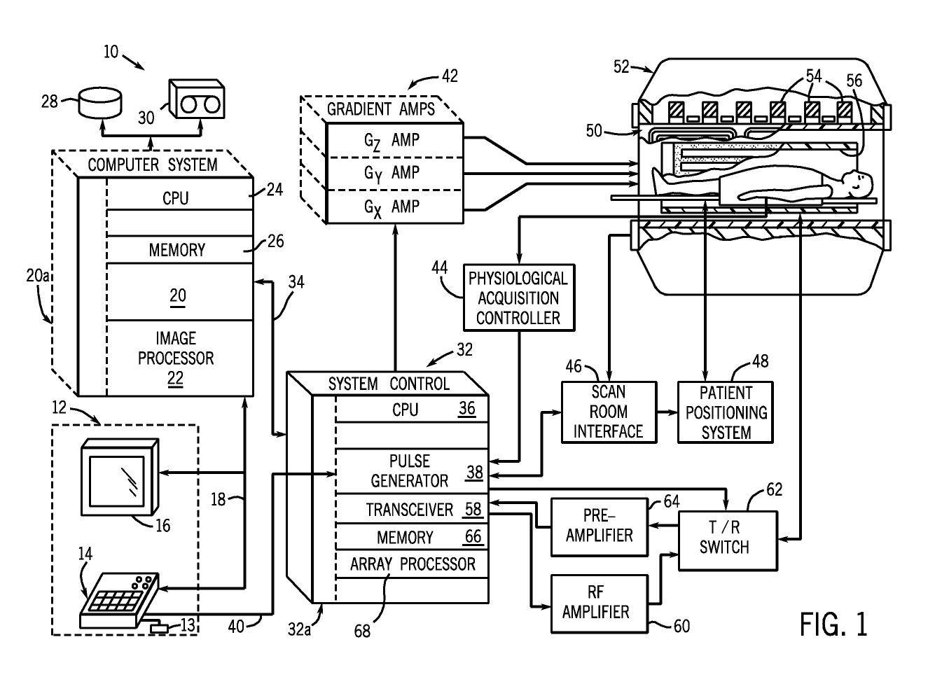

Referring to FIG. 1, superconducting magnet system 10 in an example comprises a superconducting magnet systems operating in an alternating current (AC) environment. Exemplary superconducting magnet systems comprise a transformer, a generator, a motor, superconducting magnet energy storage (SMES), and/or a magnetic resonance (MR) system. Although a conventional MR magnet operates in a DC mode, some MR magnets may operate under an AC magnetic field from the gradient coils when the gradient leakage field to the magnet is high. Such an AC magnetic field generates AC losses in the magnet. An illustrative discussion of exemplary details of a magnetic resonance and/or magnetic resonance imaging (MRI) apparatus and/or system are presented, for explanatory purposes.

The operation of the system is controlled from an operator console 12 which includes a keyboard or other input device 13, a control panel 14, and a display screen 16. The console 12 communicates through a link 18 with a separate computer system 20 that enables an operator to control the production and display of images on the display screen 16. The computer system 20 includes a number of modules which communicate with each other through a backplane 20a. These include an image processor module 22, a CPU module 24 and a memory module 26, known in the art as a frame buffer for storing image data arrays. The computer system 20 is linked to disk storage 28 and removable storage 30 for storage of image data and programs, and communicates with a separate system control 32 through a high speed serial link 34. The input device 13 can include a mouse, joystick, keyboard, track ball, touch activated screen, light wand, voice control, or any similar or equivalent input device, and may be used for interactive geometry prescription.

The system control 32 includes a set of modules connected together by a backplane 32a. These include a CPU module 36 and a pulse generator module 38 which connects to the operator console 12 through a serial link 40. It is through link 40 that the system control 32 receives commands from the operator to indicate the scan sequence that is to be performed. The pulse generator module 38 operates the system components to carry out the desired scan sequence and produces data which indicates the timing, strength and shape of the RF pulses produced, and the timing and length of the data acquisition window. The pulse generator module 38 connects to a set of gradient amplifiers 42, to indicate the timing and shape of the gradient pulses that are produced during the scan. The pulse generator module 38 can also receive patient data from a physiological acquisition controller 44 that receives signals from a number of different sensors connected to the patient, such as ECG signals from electrodes attached to the patient. And finally, the pulse generator module 38 connects to a scan room interface circuit 46 which receives signals from various sensors associated with the condition of the patient and the magnet system. It is also through the scan room interface circuit 46 that a patient positioning system 48 receives commands to move the patient to the desired position for the scan.

The gradient waveforms produced by the pulse generator module 38 are applied to the gradient amplifier system 42 having Gx, Gy, and Gz amplifiers. Each gradient amplifier excites a corresponding physical gradient coil in a gradient coil assembly generally designated 50 to produce the magnetic field gradients used for spatially encoding acquired signals. The gradient coil assembly 50 forms part of a magnet assembly 52 which includes a polarizing magnet 54 and a whole-body RF coil 56. A transceiver module 58 in the system control 32 produces pulses which are amplified by an RF amplifier 60 and coupled to the RF coil 56 by a transmit/receive switch 62. The resulting signals emitted by the excited nuclei in the patient may be sensed by the same RF coil 56 and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 38 to electrically connect the RF amplifier 60 to the coil 56 during the transmit mode and to connect the preamplifier 64 to the coil 56 during the receive mode. The transmit/receive switch 62 can also enable a separate RF coil (for example, a surface coil) to be used in either the transmit or receive mode.

The MR signals picked up by the RF coil 56 are digitized by the transceiver module 58 and transferred to a memory module 66 in the system control 32. A scan is complete when an array of raw k-space data has been acquired in the memory module 66. This raw k-space data is rearranged into separate k-space data arrays for each image to be reconstructed, and each of these is input to an array processor 68 which operates to Fourier transform the data into an array of image data. This image data is conveyed through the serial link 34 to the computer system 20 where it is stored in memory, such as disk storage 28. In response to commands received from the operator console 12, this image data may be archived in long term storage, such as on the removable storage 30, or it may be further processed by the image processor 22 and conveyed to the operator console 12 and presented on the display 16.

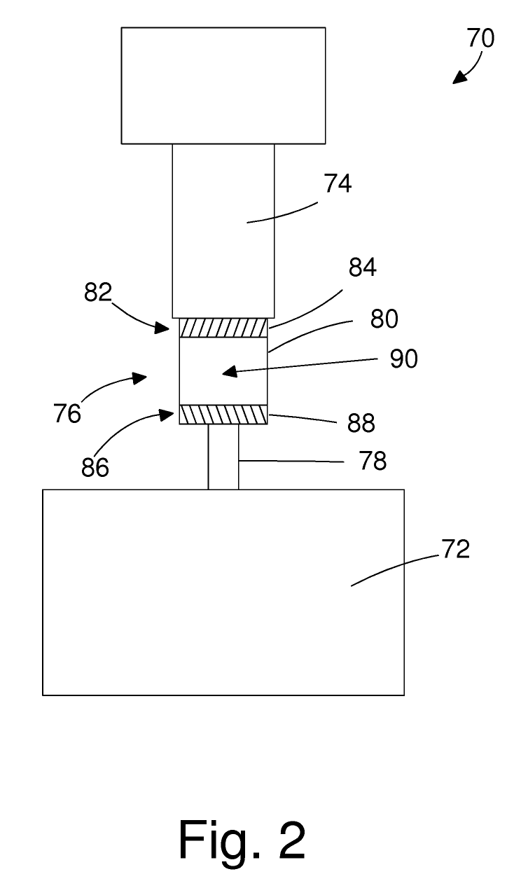

Referring to FIG. 2, a cooling system 70 for the superconducting magnet system 10 of FIG. 1 according to an embodiment of the present is shown. Magnet assembly 52 (FIG. 1) comprises a cold mass 72 for the superconducting magnet system 10. A cryocooler 74 is thermally connected to the cold mass 72 during operation of the cooling system 70 via a thermal link 76 to cool the cold mass 72 to cryogenic temperatures. In a preferred embodiment, a thermal bus-bar 78 thermally connects thermal link 76 to the cold mass 72.

Thermal link 76 includes a low thermal conductance enclosure 80 sealed at a first end 82 by a condenser plate 84 and sealed at a second end 86 by an evaporator plate 88. Enclosure 80 has low thermal conductance and is preferably a thin-walled tube constructed of a thermally insulative material such as stainless steel, such that thermal conduction between the condenser plate 84 and the evaporator plate 88 and through the enclosure 80 is minimized. Enclosure 80 is filled with a working fluid 90 that transfers heat via phase change between the condenser plate 84 and the evaporator plate 88 when the cryocooler 74 is operational. It is contemplated that working fluid 90 may be selected based on the desired operating temperature of the cold mass 72 and the operating temperature of the cryocooler 74. For example, helium may be selected for 2-5 K cryocooler operation, hydrogen for 14-24 K cryocooler operation, neon for 25-32 K cryocooler operation, and nitrogen for 65-95 K cryocooler operation. Condenser plate 84 and evaporator plate 88 are preferably made from a high thermal conductivity material such as copper and have high thermal conductance.

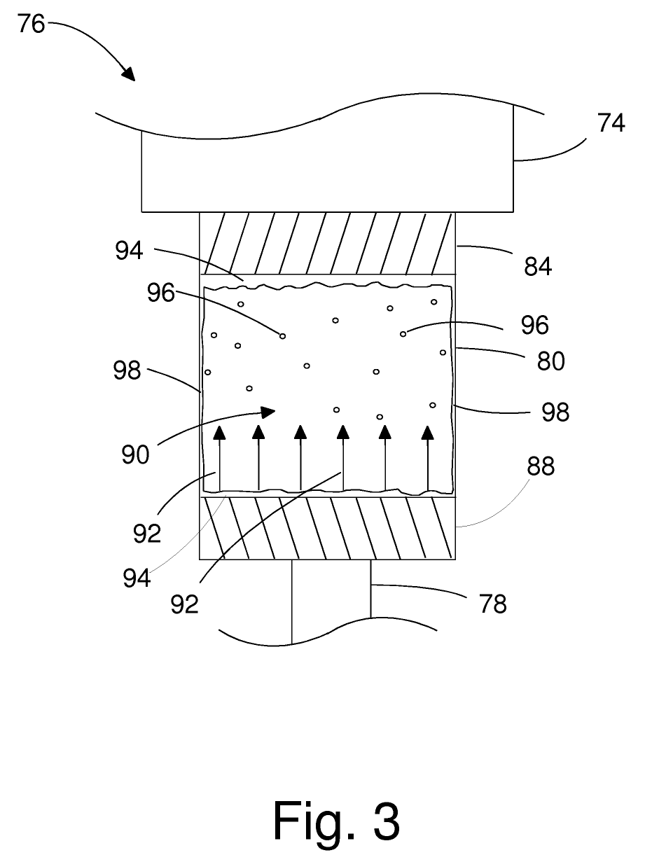

FIG. 3 shows operation of a thermodynamic cycle of thermal link 76 during normal, cooling operation. Cryocooler 74 maintains condenser plate 84 at a temperature below that of evaporator plate 88 and below the condensation temperature of the working fluid 90. Condenser plate 84 is disposed gravitationally above evaporator plate 88. Fluid evaporation 92 occurs when working fluid 90, as a condensate, or liquid 94, comes in contact with evaporator plate 88, which has a temperature above the boiling temperature of the working fluid 90. As such, working fluid 90 converts to a vapor, or gaseous state 96. Working fluid 90 in the gaseous state 96 comes in contact with condenser plate 84.

Because end plate 84 is maintained at a temperature below that of evaporator plate 88 and below the condensation temperature of working fluid 90, fluid in gaseous state 96 condenses to liquid 94 on condenser plate 84. Liquid 94, being disposed gravitationally above evaporator plate 88, flows 98 down along the enclosure 80 and back to evaporator plate 88. Liquid 94 may additionally drip from condenser plate 84 to evaporator plate 88.

The thermodynamic cycle described above operates in low conductance enclosure 80 wherein a continuous mass flow of working fluid 90 is cycled from evaporator plate 88 to condenser plate 84 and back again, during normal operation of cryocooler 74. Working fluid 90, by changing from liquid 94 to the gaseous state 96 through the aforementioned thermodynamic cycle, requires energy to overcome molecular forces of attraction in order to undergo a change to the gaseous state 96 during fluid evaporation 92. The amount of energy required to change working fluid 90 from liquid 94 to the gaseous state 96 at constant temperature, and back again, is known as the latent heat of vaporization. Thus, working fluid 90 serves as an efficient heat transfer medium wherein energy from cold mass 72 is extracted through thermal link 76 by operation of cryocooler 74 during normal operation of the superconducting magnet system 10.

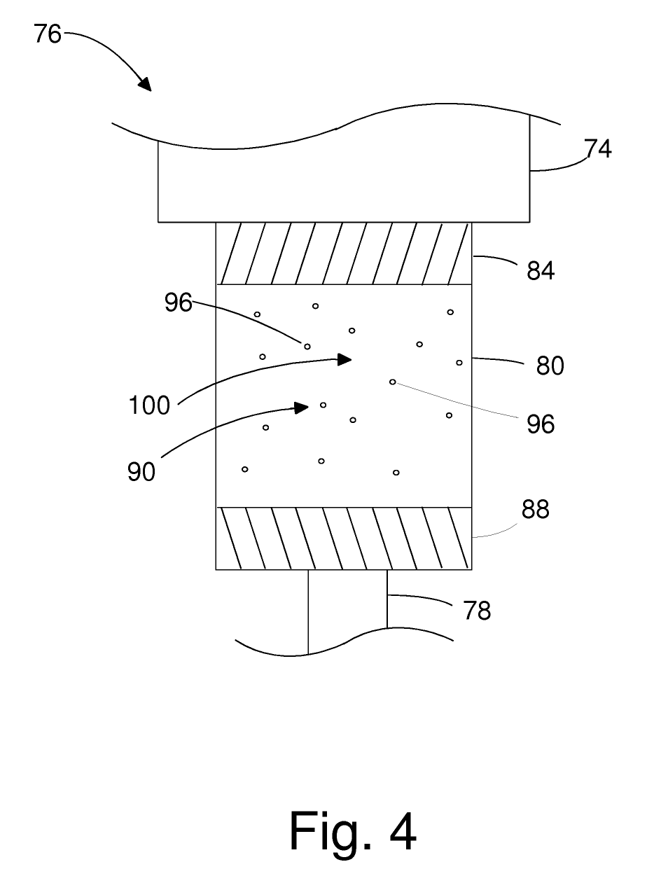

Operation of the thermodynamic cycle described with regard to FIG. 3 may be interrupted or suspended due to device failure of the cryocooler 74 or removal thereof from service for scheduled maintenance or replacement. The suspension of operation causes the cryocooler 74 to fail to maintain the temperature of the condenser plate 84 below the condensation temperature of the working fluid 90. During such interruption, thermal link 76 automatically thermally disconnects cryocooler 74 from cold mass 72 as described below with regard to FIG. 4. Upon activation of cryocooler 74 after shutdown, cryocooler 74 drives the temperature of the condenser plate 84 to a temperature below the condensation temperature of the working fluid 90, at which time the thermodynamic cycle described above will automatically re-start, and thermal connection via phase change heat transfer between cryocooler 74 and cold mass 72 will once again be established.

Referring now to FIG. 4, once cryocooler 74 operation is suspended, the temperature of condenser plate 84 increases to a temperature above the temperature of evaporator plate 88. Such reversal of temperatures from normal operation will halt the thermodynamic cycle described above and phase change heat transfer will substantially cease. Accordingly, evaporator plate 88 will track the temperature of the cold mass 72 and condenser plate 84 will tend to warm to room temperature.

The temperature of working fluid 90 will stratify within low conductance enclosure 80 with working fluid 90 being coldest at evaporator plate 88 and increasing in temperature toward condenser plate 84. As such, heat transfer between condenser plate 84 and evaporator plate 88 will be reduced, due to the cessation of phase change heat transfer. Heat transfer will be limited to the parallel paths of conduction through gaseous volume 100 and conduction through low conductance enclosure 80. Due to the low thermal conductivity of gaseous volume 100 and the low conductance of the low conductance enclosure 80, heat transfer in thermal link 76 will substantially cease, and cryocooler 74 and cold mass 72 will be substantially thermally disconnected. In this manner, the ride-through time allowing operation of the magnet assembly 52 at superconducting temperatures will not be decreased due to heat being transferred from the non-operational cryocooler 74 to the cold mass 72. One skilled in the art will recognize that the aforementioned operation of thermal link 76 is automatic and occurs with no moving mechanical parts.

The present invention provides automatic thermal disconnection of a cryocooler from a cold mass device. Upon cessation of operation of the cryocooler, phase change heat transfer within the thermal link ceases, substantially minimizing heat transfer and enabling continued operation of the magnet during the ride-through time. Selection by appropriate design of the low conductance enclosure and the working fluid allows a reduction of the number of superconducting magnet quenches that occur due to unplanned outages of the cryocooler. Furthermore, superconducting magnet systems are able to sustain short durations during which loss of the cryocooler occurs due to planned maintenance or repair of the cryocooler.

Therefore a cryocooler thermal link includes a first end plate configured to be thermally connected to a cryocooler and a second end plate configured to be thermally connected to a cold mass. A wall encloses a space between the first and the second end plates and has a first end attached to the first end plate and a second end attached to the second end plate. The cryocooler thermal link also includes a working fluid positioned in the space.

The present invention is also directed to an MRI system including a superconducting magnet assembly cold mass, a cryocooler, and a thermal switch positioned between the cold mass and the cryocooler. The thermal switch includes a first end plate in thermal contact with the cryocooler and a second end plate in thermal contact with the cold mass. A wall is connected to the first end plate and the second end plate forming an enclosure. A working fluid is contained in the enclosure and is in thermal contact with the first end plate and the second end plate.

The present invention is also direct to a method of controlling heat transfer between a cryocooler having a first end plate and a cold mass having a second end plate. The method includes the steps of forming an enclosure between the first end plate and the second end plate, orienting the first end plate gravitationally above the second end plate, and filling the enclosure with a working fluid. The working fluid is in thermal contact with the first end plate and the second end plate.

The present invention has been described in terms of the preferred embodiment, and it is recognized that equivalents, alternatives, and modifications, aside from those expressly stated, are possible and within the scope of the appending claims.

1. A cryocooler thermal link comprising:
a first end plate configured to be thermally connected to a cryocooler;
a second end plate configured to be thermally conductively connected to a cold mass;
a wall enclosing a space between the first and the second end plates, the wall having a first end attached to the first end plate and a second end attached to the second end plate; and
a working fluid positioned in the space.

2. The cryocooler thermal link of claim 1 wherein the first end plate is positioned gravitationally above the second end plate.

3. The cryocooler thermal link of claim 2 wherein the temperature of the first end plate is below the temperature of the second end plate.

4. The cryocooler thermal link of claim 3 wherein the temperature of the first end plate is below the condensing temperature of the working fluid.

5. The cryocooler thermal link of claim 4 having condensate of the working fluid formed on the first end plate.

6. The cryocooler thermal link of claim 3 wherein the temperature of the second end plate is above the boiling temperature of the working fluid.

7. The cryocooler thermal link of claim 2 wherein the temperature of the first end plate is above the temperature of the second end plate.

8. The cryocooler thermal link of claim 7 wherein the temperature of the working fluid is stratified within the space.

9. The cryocooler thermal link of claim 1 wherein the thermal conductance of the wall enclosing the space is less than a thermal conductance of one of the first end plate and the second end plate.

10. The cryocooler thermal link of claim 9 wherein the wall comprises stainless steel.

11. The cryocooler thermal link of claim 1 wherein the working fluid is one of helium, hydrogen, neon, and nitrogen.

12. An MRI system comprising:
a superconducting magnet assembly cold mass;
a cryocooler; and
a thermal switch positioned between the cold mass and the cryocooler, the thermal switch comprising:
a first end plate in thermal contact with the cryocooler;
a second end plate in conductive thermal contact with the cold mass;
a wall connected to the first end plate and the second end plate forming an enclosure; and
a working fluid contained in the enclosure;
wherein the working fluid is in thermal contact with the first end plate and the second end plate.

13. The MRI system of claim 12 further comprising a thermal bus-bar in conductive thermal contact with the second end plate and the cold mass.

14. The MRI system of claim 12 when the cryocooler is in operating mode wherein a temperature of the first plate is cooled below a temperature of the second plate.

15. The MRI system of claim 12 when the cryocooler is not in operating mode wherein a temperature of the second end plate is below a temperature of the first end plate.

16. The MRI system of claim 12 wherein the working fluid is one of helium, hydrogen, neon, and nitrogen.

17. A method of controlling heat transfer between a cryocooler having a first end plate and a cold mass having a second end plate, the method comprising the steps of:
forming an enclosure between the first end plate and the second end plate, the second end plate configured to be in conductive thermal contact with the cold mass;
orienting the first end plate gravitationally above the second end plate; and
filling the enclosure with a working fluid, wherein the working fluid is in thermal contact with the first end plate and the second end plate.

18. The method of claim 17 further comprising the step of transferring heat within the enclosure wherein a first rate of heat transfer occurs within the enclosure during operation of the cryocooler, and a second rate of heat transfer occurs within the enclosure during suspension of operation of the cryocooler, the first rate being greater than the second rate.

19. The method of claim 18 wherein the first rate of heat transfer is directed from the second end plate to the first end plate, and the second rate of heat transfer is directed from the first end plate to the second end plate.

20. The method of claim 17 wherein the enclosure is formed using stainless steel.

21. The method of claim 17 wherein the filling is with a working fluid comprising one of helium, hydrogen, neon, and nitrogen.
